(19) United States
(12) Patent Application Publication
(10) Pub. No.: US 2019/0072605 A1
(43) Pub. Date: Mar. 7, 2019

(54) ELECTRONIC COMPONENT HANDLER AND ELECTRONIC COMPONENT TESTER

(71) Applicant: SEIKO EPSON CORPORATION, Tokyo (JP)

(72) Inventor: Yasutoshi NATSUIZAKA, Matsumoto (JP)

(73) Assignee: Seiko Epson Corporation, Tokyo (JP)

(21) Appl. No.: 16/079,594

(22) PCT Filed: Dec. 8, 2016
(86) PCT No.: PCT/JP2016/086645

§ 371 Date: Aug. 24, 2018

(30) Foreign Application Priority Data
Feb. 26, 2016 (JP) 2016-035345

(51) Int. Cl. G01R 31/28; H01L 21/673; H01L 21/687; H01L 21/67

(52) U.S. Cl. CPC G01R 31/2867; G01R 31/2891; H01L 21/67259; H01L 21/68764; H01L 21/67333

(57) ABSTRACT

An electronic component handler and an electronic component tester for accurately detecting positional information of a holding unit are to be provided. The electronic component handler includes: a holding unit which holds an electronic component; a base portion on which the holding unit is movably disposed; a position detecting unit which detects a relative position between the base portion and the holding unit; a driving unit which drives the holding unit; a control unit which controls driving of the driving unit; and a waveform converting unit which is provided between the position detecting unit and the control unit and converts a waveform of an output signal output by the position detecting unit.

### BACKGROUND

### Technical Field

The present invention relates to an electronic component handler and an electronic component tester.

### Related Art

From the related art, an electronic component tester which tests electric characteristics of an electronic component, such as an IC device, is known, and an electronic component handler for transporting the IC device is incorporated in the electronic component tester (for example, refer to JP-A-08-233901).

In addition, in the electronic component tester, by placing a plurality of IC devices on a tray and inserting the IC devices into the apparatus together with the tray, the tray is transported to a test unit in which test is performed by a transport unit (holding unit). In addition, when the test is completed, the IC device is placed on the tray, transported together with the tray after the test by the transport unit, and discharged to the outside of the apparatus.

In the electronic component handler, an encoder for detecting positional information of the transport unit is embedded in the transport unit. The positional information detected by the encoder is transmitted to a control unit. The control unit controls the transport unit based on the transmitted positional information.

However, noise may be superimposed on an output signal of the positional information of the transport unit output by the encoder due to the influence of electric power applied to members around the encoder, such as a motor or a piezo element. In this case, depending on the degree of noise, it becomes difficult to accurately detect the positional information of the transport unit.

### SUMMARY

The present invention has been made to solve at least a part of the above-described problems, and can be realized as the following embodiments or application examples.

An electronic component handler according to the present invention includes: a holding unit which holds an electronic component; a base portion on which the holding unit is movably disposed; a position detecting unit which detects a relative position between the base portion and the holding unit; a driving unit which drives the holding unit; a control unit which controls driving of the driving unit; and a waveform converting unit which is provided between the position detecting unit and the control unit and converts a waveform of an output signal output by the position detecting unit.

Accordingly, it is possible to reduce the influence when noise caused by, for example, a voltage or the like applied to the driving unit is superimposed on the output signal output by the position detecting unit. Accordingly, it is possible to improve an SN ratio of the output signal output by the position detecting unit. As a result, it is possible to more accurately detect positional information of the holding unit.

In the electronic component handler of the present invention, it is preferable that the control unit is electrically connected to the position detecting unit via the waveform converting unit.

Accordingly, it is possible to more reliably achieve the effect of the present invention.

In the electronic component handler of the present invention, it is preferable that the waveform converting unit amplifies a voltage of the output signal.

Accordingly, it is possible to further reduce the influence when noise is superimposed on the output signal.

In the electronic component handler of the present invention, it is preferable that the waveform converting unit amplifies the voltage of the output signal by 2 times or more and 10 times or less.

Accordingly, it is possible to more effectively reduce the influence when noise is superimposed on the output signal.

In the electronic component handler of the present invention, it is preferable that the position detecting unit is an encoder.

Accordingly, it is possible to accurately detect a position of the holding unit.

In the electronic component handler of the present invention, it is preferable that a plurality of the driving units and the encoders are provided.

Accordingly, it is possible to finely adjust positions of more driving units, and to detect the position of more holding units.

In the electronic component handler of the present invention, it is preferable that, when three axes that cross each other are respectively set as an X axis, a Y axis, and a Z axis, the driving unit includes an X-axis driving unit which drives the holding unit in the X-axis direction, a Y-axis driving unit which drives the holding unit in the Y-axis direction, and a Z-axis driving unit which rotates the holding unit around the Z axis, and the encoder includes an X-axis encoder which detects a position of the holding unit driven by the X-axis driving unit in the X-axis direction, a Y-axis encoder which detects a position of the holding unit driven by the Y-axis driving unit in the Y-axis direction, and a Z-axis encoder which detects a position of the holding unit driven by the Z-axis driving unit around the Z axis.

Accordingly, it is possible to finely adjust the position of the holding unit in the X-axis direction, in the Y-axis direction, and around the Z axis. Furthermore, it is possible to detect the position of the holding unit in the X-axis direction, in the Y-axis direction, and around the Z axis.

In the electronic component handler of the present invention, it is preferable that, when the X-axis driving unit and the X-axis encoder are X-axis units, the Y-axis driving unit and the Y-axis encoder are Y-axis units, and the Z-axis driving unit and the Z-axis encoder are Z-axis units, a plurality of the X-axis units, the Y-axis units, and the Z-axis units are provided.

Accordingly, it is possible to accurately detect the position of more holding units.

In the electronic component handler of the present invention, it is preferable that the waveform converting unit has a function of converting the output signal into a signal of which an error is detectable.

Accordingly, it is possible to further improve an SN ratio of the output signal output by the encoder. As a result, it is possible to more accurately detect the positional information of the holding unit.

In the electronic component handler of the present invention, it is preferable that a plurality of the waveform converting units are provided, and each of the waveform converting units is electrically connected to each other and one waveform converting unit of each of the waveform converting units is electrically connected to the control unit.

Accordingly, it is possible to reduce the number of wirings between the waveform converting unit and the control unit. Accordingly, it is possible to make it difficult for noise to be superimposed on the output signal.

In the electronic component handler of the present invention, it is preferable that the driving unit includes a piezo actuator that serves as a driving source.

Accordingly, it is possible to accurately finely adjust the position of the holding unit.

In the electronic component handler of the present invention, it is preferable that a support substrate which supports the holding unit is provided, and the waveform converting unit is disposed on the support substrate.

Accordingly, the waveform converting unit is installed as close to the encoder as possible. As a result, it is possible to more accurately detect the positional information of the holding unit.

In the electronic component handler of the present invention, it is preferable that the holding unit is disposed in a test region where test of the electronic component is performed.

Accordingly, it is possible to accurately detect the position of the holding unit disposed in the test region.

An electronic component tester according to the present invention includes: a holding unit which holds an electronic component; a base portion on which the holding unit is movably disposed; a position detecting unit which detects a relative position between the base portion and the holding unit; a driving unit which drives the holding unit; a control unit which controls driving of the driving unit; a waveform converting unit which is provided between the position detecting unit and the control unit and converts a waveform of an output signal output by the position detecting unit; and a test unit which tests the electronic component.

Accordingly, it is possible to reduce the influence when noise caused by, for example, the voltage or the like applied to the driving unit is superimposed on the output signal output by the position detecting unit. Accordingly, it is possible to improve the SN ratio of the output signal output by the encoder. As a result, it is possible to more accurately detect the positional information of the holding unit.

### BRIEF DESCRIPTION OF DRAWINGS

FIG. 1 is a schematic perspective view when an embodiment of an electronic component tester of the present invention is viewed from a front side.

FIG. 2 is a schematic plan view illustrating an operation state of the electronic component tester illustrated in FIG. 1.

FIG. 3 is a block diagram of the electronic component tester illustrated in FIG. 1.

FIG. 4 is a side view of a device transport head included in the electronic component tester illustrated in FIG. 1.

FIG. 5 is another block diagram of the electronic component tester illustrated in FIG. 1.

FIG. 6 is a graph illustrating a time-dependent change in an output signal output by a relay board included in the electronic component tester illustrated in FIG. 1.

FIG. 7 is a graph illustrating a time-dependent change in an output signal output by an encoder included in an electronic component tester of the related art.

FIG. 8 is a perspective view illustrating a robot which is a modification example of an electronic component handler and the electronic component tester of the present invention.

### DETAILED DESCRIPTION

Hereinafter, an electronic component handler and an electronic component tester of the present invention will be described in detail based on appropriate embodiments illustrated in the attached drawings.

### First Embodiment

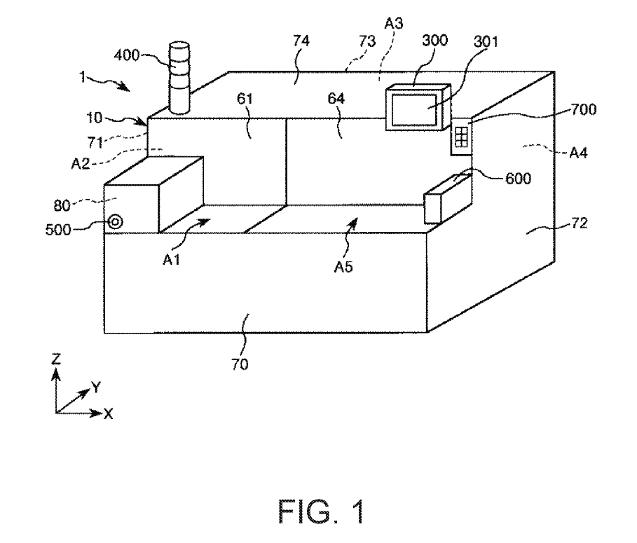

Hereinafter, a first embodiment of the electronic component handler and the electronic component tester of the present invention will be described with reference to FIGS. 1 to 7. In addition, hereinafter, for the convenience of the description, as illustrated in FIGS. 1, 2, and 4, three axes which are orthogonal to each other are respectively set as an X axis, a Y axis, and a Z axis as an example of three axes which cross each other. In addition, an XY plane including the X axis and the Y axis is horizontal, and the Z axis is perpendicular. In addition, a direction parallel to the X axis is also referred to as “X direction”, a direction parallel to the Y axis is also referred to as “Y direction”, and a direction parallel to the Z axis is also referred to as “Z direction”. In addition, a direction in which arrows of each direction are oriented is “positive”, and a direction opposite thereto is “negative”. In addition, “horizontal” referred in the present specification is not limited to a complete horizontal state, and also includes a state of being slightly (for example, a degree which is less than 5°) inclined with respect to the horizontal state as long as transport of an electronic component is not interrupted.

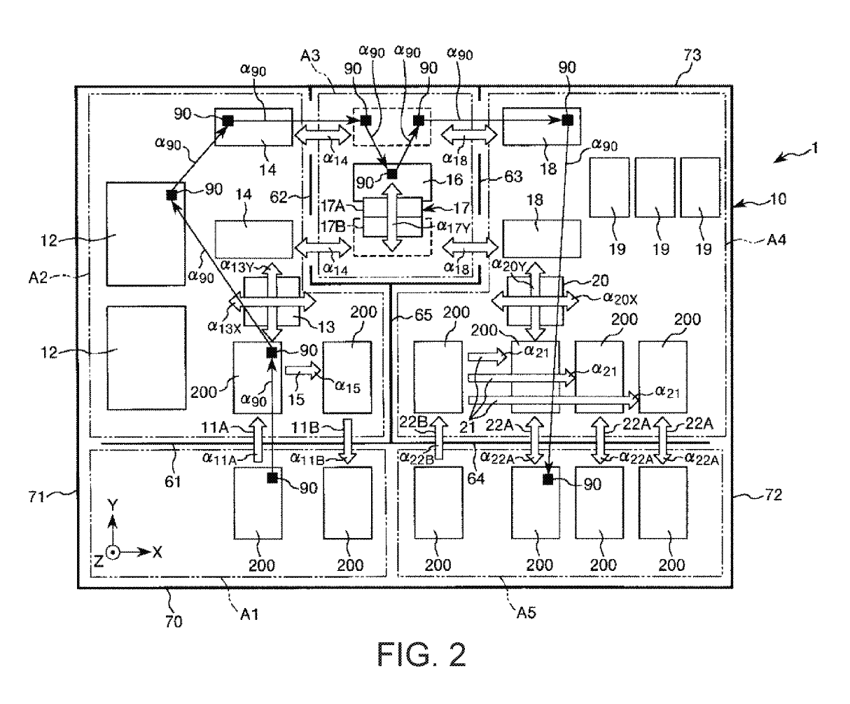

A tester 1 (electronic component tester) illustrated in FIGS. 1 and 2 includes an electronic component handler 10 and a test unit 6 which tests electronic components. The test apparatus 1 transports the electronic component, such as an IC device which is a ball grid array (BGA) package, and inspects and tests (hereinafter, simply referred to as “test”) electric characteristics in the transport process.

The test apparatus 1 includes: a suction pad 173 that serves as a holding unit which holds an IC device 90; a support substrate 171 that serves as a base portion in which the suction pad 173 is movably disposed; a position detecting unit 4 which detects a relative position between the support substrate 171 and the suction pad 173; a driving unit 3 which drives the suction pad 173; a control unit 80 which controls driving of the driving unit 3; a test unit 16 which tests the IC device 90; a relay board 5 which is provided between the position detecting unit 4 and the control unit 80, and serves as a waveform converting unit which converts the waveform of the output signal output by the position detecting unit 4; and a test unit 16 which tests the IC device 90.

The electronic component handler 10 is an apparatus which transports the electronic components, and includes: the suction pad 173 that serves as a holding unit which holds the IC device 90; the support substrate 171 that serves as a base portion in which the suction pad 173 is movably disposed; the position detecting unit 4 which detects a relative position between the support substrate 171 and the suction pad 173; the driving unit 3 which drives the suction pad 173; the control unit 80 which controls driving of the driving unit 3; the test unit 16 which tests the IC device 90; and the relay board 5 which is provided between the position detecting unit 4 and the control unit 80, and serves as a waveform converting unit which converts the waveform of the output signal output by the position detecting unit 4.

In addition, hereinafter, for the convenience of the description, a case where the IC device which functions as the electronic component is used will be described as a representative example, and this will be referred to as “IC device 90”. The IC device 90 is placed on a placing member which is a tray 200.

The test apparatus 1 is divided into a tray supply region A1, a device supply region (hereinafter, simply referred to as “supply region”) A2, a test region A3, a device collect region A4 (hereinafter, simply referred to as “collect region”), and a tray remove region A5. In addition, the IC device 90 is tested in the test region A3 in the middle of the path via each of the regions from the tray supply region A1 to the tray remove region A5 in order in an arrow α₉₀ direction. In this manner, the test apparatus 1 includes the electronic component handler 10 (handler) which transports the IC device 90 in each of the regions, and the test unit 16 which performs the test in the test region A3. In addition to this, the test apparatus 1 includes a monitor 300, a signal lamp 400, and an operation panel 700.

In addition, the test apparatus 1 is used while a part at which the tray supply region A1 and the tray remove region A5 are disposed, that is, a lower side in FIG. 2, is a front side, and a part in which the test region A3 is disposed, that is, an upper side in FIG. 2, is a rear side.

The tray supply region A1 is a material supply unit into which the tray 200 on which the plurality of IC devices 90 in a state of not being tested are arranged is supplied. In the tray supply region A1, it is possible to stack multiple trays 200.

The supply region A2 is a region through which the plurality of IC devices 90 on the tray 200 transported from the tray supply region A1 are respectively supplied to the test region A3. In addition, tray transport mechanisms 11A and 11B which transport the trays 200 in the horizontal direction one by one are provided to go across the tray supply region A1 and the supply region A2. The tray transport mechanism 11A is a moving unit which can move the tray 200 to the positive side in the Y direction for each of the IC devices 90 placed on the tray 200, that is, in an arrow α_{11A} direction in FIG. 2. Accordingly, it is possible to stably send the IC device 90 into the supply region A2. In addition, the tray transport mechanism 11B is a moving unit which can move the empty tray 200 to the negative side in the Y direction, that is, in an arrow α_{11B} direction in FIG. 2. Accordingly, it is possible to move the empty tray 200 from the supply region A2 to the tray supply region A1.

In the supply region A2, the temperature adjustment unit (soak plate) 12, a device transport head 13, and a tray transport mechanism 15, are provided.

The temperature adjustment unit 12 is a unit on which the plurality of IC devices 90 are placed and can collectively heat the IC devices 90, and is called “soak plate”. By using the soak plate, it is possible to heat the IC device 90 before the test by the test unit 16 in advance, and to adjust the temperature to the temperature appropriate for the test (high temperature test). In the configuration illustrated in FIG. 2, two temperature adjustment units 12 are disposed and fixed in the Y direction. In addition, the IC device 90 on the tray 200 transported in from the tray supply region A1 by the tray transport mechanism 11A is transported to any of the temperature adjustment units 12.

The device transport head 13 is supported to be movable in the X direction, in the Y direction, and further in the Z direction, in the supply region A2. Accordingly, the device transport head 13 can transport the IC device 90 between the tray 200 transported in from the tray supply region A1 and the temperature adjustment unit 12 and transport the IC device 90 between the temperature adjustment unit 12 and a device supply unit 14 which will be described later. In addition, in FIG. 2, the movement of the device transport head 13 in the X direction is illustrated as an arrow α_{13X}, and the movement of the device transport head 13 in the Y direction is illustrated as an arrow α_{13Y}.

The tray transport mechanism 15 is a mechanism which transports the empty tray 200 in a state where all of the IC devices 90 are removed to the positive side in the X direction in the supply region A2, that is, in an arrow α₁₅ direction. In addition, after the transport, the empty tray 200 returns to the tray supply region A1 from the supply region A2 by the tray transport mechanism 11B.

The test region A3 is a region in which the IC device 90 is tested. In the test region A3, the test unit 16 and a device transport head 17 are provided. In addition, the device supply unit 14 which moves so as to go across the supply region A2 and the test region A3 and a device collect unit 18 which moves so as to go across the test region A3 and the collect region A4 are also provided.

The device supply unit 14 is configured as a placing unit on which the IC device 90 of which the temperature is adjusted by the temperature adjustment unit 12 is placed and which can transport the IC device 90 to the vicinity of the test unit 16, and is also called “shuttle plate for supply” or simply “supply shuttle”.

In addition, the device supply unit 14 is supported to be capable of reciprocating between the supply region A2 and the test region A3 along the X direction, that is, along an arrow α₁₄ direction. In the configuration illustrated in FIG. 2, two device supply units 14 are disposed in the Y direction, and the IC device 90 on the temperature adjustment unit 12 is transported to any of the device supply units 14. In addition, similar to the temperature adjustment unit 12, the device supply unit 14 is configured to be capable of heating the IC device 90 placed on the device supply unit 14. Accordingly, with respect to the IC device 90 of which the temperature is adjusted by the temperature adjustment unit 12, it is possible to maintain the temperature adjustment state, and to transport the IC device 90 to the vicinity of the test unit 16 of the test region A3.

The device transport head 17 is an operation unit which holds the IC device 90 maintained in the temperature adjustment state, and transports the IC device 90 in the test region A3. The device transport head 17 is a part of a mechanism which is supported to be capable of reciprocating in the Y direction and in the Z direction in the test region A3, and is called “index arm”. Accordingly, the device transport head 17 can transport and place the IC device 90 on the device supply unit 14 transported in from the device supply region A2 onto the test unit 16. In addition, in FIG. 2, the reciprocating movement of the device transport head 17 in the Y direction is illustrated by an arrow α_{17Y}. In addition, the device transport head 17 is supported to be capable of reciprocating in the Y direction and in the Z direction, but not being limited thereto, the device transport head 17 may also be supported to be capable of reciprocating in the X direction.

In addition, similar to the temperature adjustment unit 12, the device transport head 17 is configured to be capable of heating the held IC device 90. Accordingly, the temperature adjustment state in the IC device 90 can be continuously maintained from the device supply unit 14 to the test unit 16.

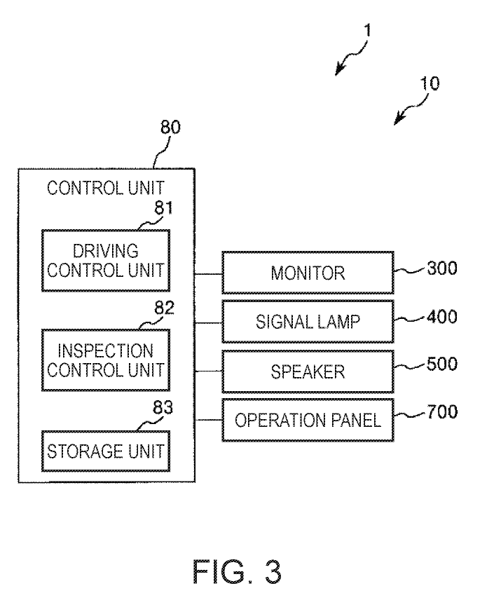

The test unit 16 is configured as a placing unit on which the IC device 90 which is the electronic component is placed and inspects and tests (tests) the electric characteristics of the IC device 90. In the test unit 16, a plurality of probe pins which are electrically connected to a terminal portion of the IC device 90 are provided. In addition, as the terminal portion of the IC device 90 and the probe pin are electrically connected to each other, that is, come into contact with each other, the IC device 90 can be tested. The test of the IC device 90 is performed based on a program which is stored in a storage unit 83 (refer to FIG. 3) of the control unit 80. In addition, even in the test unit 16, similar to the temperature adjustment unit 12, the IC device 90 can be heated, and the temperature of the IC device 90 can be adjusted to the temperature appropriate for the test.

In addition, the test unit 16, the temperature adjustment unit 12, the device supply unit 14, and the device transport head 17 maybe respectively configured to be capable of cooling the IC device 90 in addition to being capable of heating the IC device 90.

The device collect unit 18 is configured as a placing unit on which the IC device 90 to which the test by the test unit 16 is finished is placed and which can transport the IC device 90 to the collect region A4, and is also called “shuttle plate for collection” or simply “collect shuttle”.

In addition, the device collect unit 18 is supported to be capable of reciprocating in the X direction between the test region A3 and the device collect region A4, that is, along an arrow α₁₈ direction. In addition, in the configuration illustrated in FIG. 2, similar to the device supply unit 14, two device collect units 18 are disposed in the Y direction, and the IC device 90 on the test unit 16 is transported to any of the device collect units 18, and is placed. The transport to the device collect unit 18 is performed by the device transport head 17.

The collect region A4 is a region in which the plurality of IC devices 90 which are tested are collected. In the collect region A4, a tray for collection 19, a device transport head 20, and a tray transport mechanism 21 are provided. In addition, in the collect region A4, the empty tray 200 is also prepared.

The tray for collection 19 is a placing unit on which the IC device 90 tested by the test unit 16 is placed, and is fixed not to move in the collect region A4. Accordingly, even in the collect region A4 in which a relatively large number of various types of movable units, such as the device transport head 20, are disposed, and on the tray for collection 19, the IC device 90 which is already tested is stably placed. In addition, in the configuration illustrated in FIG. 2, three trays for collection 19 are disposed along the X direction.

In addition, three empty trays 200 are also disposed along the X direction. The empty tray 200 is also a placing unit on which the IC device 90 tested by the test unit 16 is placed. In addition, the IC device 90 on the device collect unit 18 that has moved to the collect region A4 is transported to any of the tray for collection 19 and the empty tray 200, and is placed. Accordingly, the IC device 90 is classified for each of the test result, and is collected.

The device transport head 20 is supported to be movable in the X direction, in the Y direction, and further in the Z direction, in the collect region A4. Accordingly, the device transport head 20 can transport the IC device 90 to the tray for collection 19 or the empty tray 200 from the device collect unit 18. In addition, in FIG. 2, the movement of the device transport head 20 in the X direction is illustrated by an arrow α_{20X}, and the movement of the device transport head 20 in the Y direction is illustrated by an arrow α_{20Y}.

The tray transport mechanism 21 is a mechanism which transports the empty tray 200 transported in from the tray remove region A5 in the X direction in the collect region A4, that is, in an arrow α₂₁ direction. In addition, after the transport, the empty tray 200 can be disposed at a position at which the IC device 90 is collected, that is, can be any of the three empty trays 200.

The tray remove region A5 is a material remove unit which collects and removes the tray 200 on which the plurality of IC devices 90 in a tested state are arranged. In the tray remove region A5, it is possible to stack multiple trays 200.

In addition, tray transport mechanisms 22A and 22B which transport the trays 200 in the Y direction one by one are provided to go across the collect region A4 and the tray remove region A5. The tray transport mechanism 22A is a moving unit which can allow the tray 200 to reciprocate in the Y direction, that is, in an arrow α_{22A} direction. Accordingly, it is possible to transport the IC device 90 that is already tested from the collect region A4 to the tray remove region A5. In addition, the tray transport mechanism 22B can move the empty tray 200 for collecting the IC device 90 to the positive side in the Y direction, that is, in an arrow α_{22B} direction. Accordingly, it is possible to move the empty tray 200 from the tray remove region A5 to the collect region A4.

In the test apparatus 1, the tray supply region A1 and the supply region A2 are partitioned by a first partition wall 61, the supply region A2 and the test region A3 are partitioned by a second partition wall 62, the test region A3 and the collect region A4 are partitioned by a third partition wall 63, and the collect region A4 and the tray remove region A5 are partitioned by a fourth partition wall 64. In addition, the supply region A2 and the collect region A4 are partitioned by a fifth partition wall 65.

The most exterior of the test apparatus 1 is covered with a cover, and examples of the cover include a front cover 70, a side cover 71, a side cover 72, a rear cover 73, and a top cover 74.

As illustrated in FIG. 3, the control unit 80 includes a driving control unit 81, an test control unit 82, and the storage unit 83.

The driving control unit 81 controls, for example, operations of each unit, such as the tray transport mechanism 11A, the tray transport mechanism 11B, the temperature adjustment unit 12, the device transport head 13, the device supply unit 14, the tray transport mechanism 15, the test unit 16, the device transport head 17, the device collect unit 18, the device transport head 20, the tray transport mechanism 21, the tray transport mechanism 22A, and the tray transport mechanism 22B, which are illustrated in FIG. 1.

The test control unit 82 performs test or the like of the electrical characteristics of the IC device 90 disposed in the test unit 16 based on the program stored in the storage unit 83.

The storage unit 83 is configured with various semiconductor memories (IC memory), such as a volatile memory (for example, a RAM), a nonvolatile memory (for example, a ROM), or a rewritable (erasable and rewritable) nonvolatile memory (for example, an EPROM, an EEPROM, or a flash memory).

Further, the control unit 80 is electrically connected to the monitor 300. The operator can set or confirm an operation condition or the like of the test apparatus 1 via the monitor 300. The monitor 300 includes a display screen 301 configured of, for example, a liquid crystal screen, and is disposed in an upper portion on the front side of the test apparatus 1. As illustrated in FIG. 1, on a right side in the drawing of the tray remove region A5, a mouse table 600 on which a mouse used when operating the screen displayed on the monitor 300 is placed is provided.

In addition, at a lower right part of FIG. 1 with respect to the monitor 300, the operation panel 700 is disposed. In addition to the monitor 300, the operation panel 700 is a panel for commanding a desirable operation to the test apparatus 1.

Further, the control unit 80 is electrically connected to the signal lamp 400. By combining generated colors, the signal lamp 400 can notify an operator of an operation state or the like of the test apparatus 1. The signal lamp 400 is disposed in an upper portion of the test apparatus 1. In addition, in the test apparatus 1, a speaker 500 is embedded, and it is also possible to notify the operator of the operation state or the like of the test apparatus 1 by the speaker 500.

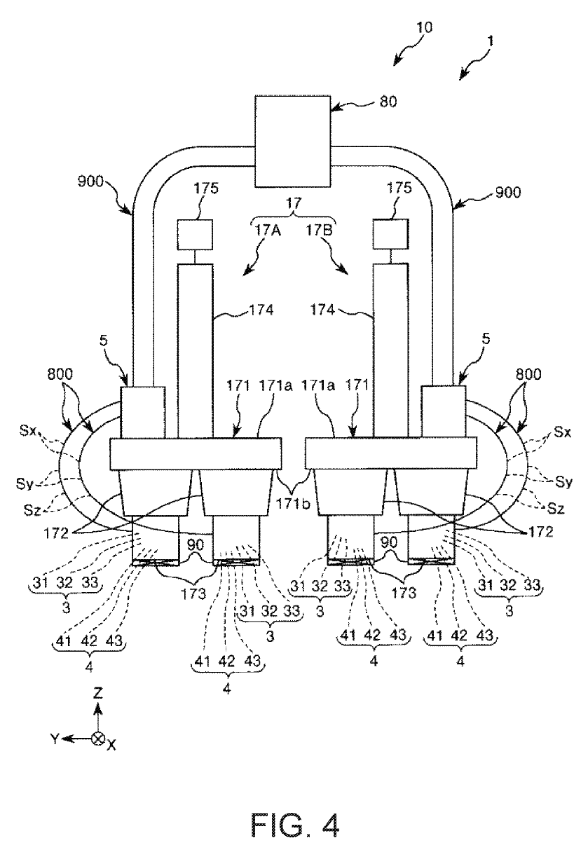

Next, the device transport head 17 will be described with reference to FIG. 4. The device transport head 17 includes a suction unit 17A and a suction unit 17B. Since the suction units 17A and 17B have the same configuration, the suction unit 17A will be representatively described below.

The suction unit 17A includes the support substrate 171, a plurality of posture changing units 172, the suction pad 173 that serves as a plurality of holding units, and a shaft 174.

The support substrate 171 is configured with a plate member of which the thickness direction is the Z-axis direction. In the support substrate 171, the posture changing unit 172 and the suction pad 173 are movably disposed. The shaft 174 is fixed to an upper surface 171a of the support substrate 171. Further, the support substrate 171 is connected to a motor 175 via the shaft 174. By the operation of the motor 175, the support substrate 171 is movable in the Z-axis direction together with the posture changing unit 172 and the suction pad 173 via the shaft 174.

On a lower surface 171b of the support substrate 171, a plurality (two in the illustrated configuration) of posture changing units 172 are fixed. Each of the posture changing units 172 has an air chamber of which the volume can be changed therein, and can be configured using, for example, an air cylinder, a diaphragm, or the like. Accordingly, when the suction pad 173 holds the IC device 90, it is possible to follow the posture of the IC device 90 while exhibiting a buffering function for the IC device 90, that is, cushioning properties. Accordingly, it is possible to safely hold the IC device 90.

On the lower side of each of the posture changing units 172, each of the suction pads 173 is disposed one by one. Each of the suction pads 173 has a suction hole (not illustrated), and the suction hole is connected to a vacuum generating apparatus, such as an ejector. Accordingly, it is possible to hold the IC device 90 by suctioning.

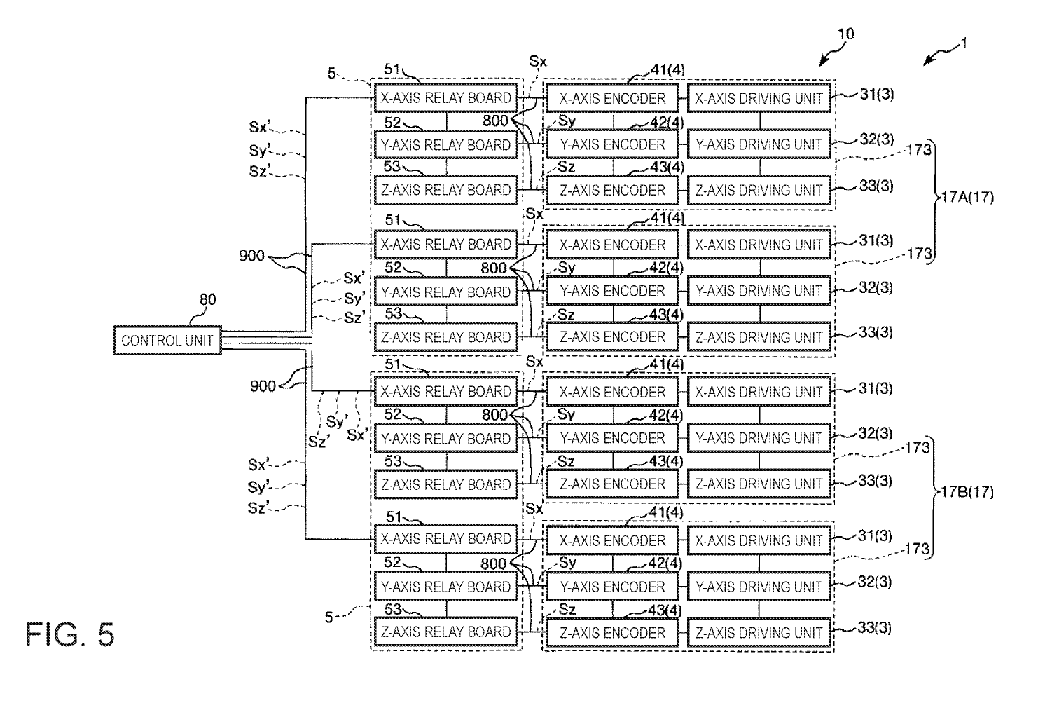

In addition, as illustrated in FIGS. 4 and 5, the suction pad 173 includes the driving unit 3 which drives the suction pad 173 and finely adjusts the position of the suction pad 173, and the position detecting unit 4 which detects the position of the suction pad 173.

The driving unit 3 includes an X-axis driving unit 31 which drives the suction pad 173 in the X-axis direction, a Y-axis driving unit 32 which drives the suction pad 173 in the Y-axis direction, and a Z-axis driving unit 33 which rotates the suction pad 173 around the Z axis. Accordingly, it is possible to finely adjust the position of the suction pad 173 in the X-axis direction, in the Y-axis direction, and around the Z axis.

The driving unit 3 has a piezo actuator that serves as a driving source. In other words, the X-axis driving unit 31, the Y-axis driving unit 32, and the Z-axis driving unit 33 are respectively configured with the piezo actuator. Accordingly, it is possible to accurately finely adjust the position of the suction pad 173.

The driving unit 3 can be configured as disclosed, for example, in “JP-A-2013-148395”, “JP-A-2013-148396”, and “JP-A-2013-148397”.

The position detecting unit 4 is an encoder and detects the relative position of the suction pad 173 with respect to the support substrate 171. In other words, the position detecting unit 4 detects the relative position between the support substrate 171 and the suction pad 173.

The position detecting unit 4 has an X-axis encoder 41, a Y-axis encoder 42, and a Z-axis encoder 43. The X-axis encoder 41 detects the position in the X-axis direction of the suction pad 173 driven by the X-axis driving unit 31. The Y-axis encoder 42 detects the position in the Y-axis direction of the suction pad 173 driven by the Y-axis driving unit 32. The Z-axis encoder 43 detects the position around Z axis of the suction pad 173 driven by the Z-axis driving unit 33. Accordingly, it is possible to detect the position of the suction pad 173 in the X-axis direction, in the Y-axis direction, and around the Z axis.

The X-axis encoder 41, the Y-axis encoder 42, and the Z-axis encoder 43 are not particularly limited and, for example, an optical encoder or the like can be used.

In the test apparatus 1, a plurality of driving units 3 and position detecting units 4 are provided respectively (in the present embodiment, two in the suction unit 17A and two in the suction unit 17B). In other words, when the X-axis driving unit 31 and the X-axis encoder 41 are X-axis units, the Y-axis driving unit 32 and the Y-axis encoder 42 are Y-axis units, and the Z-axis driving unit 33 and the Z-axis encoder 43 are Z-axis units, a plurality (two in the present embodiment) of the X-axis units, the Y-axis units, and the Z-axis units are provided respectively in the suction unit 17A and the suction unit 17B. Accordingly, it is possible to finely adjust the position of more suction pads 173, and to detect the position of more suction pads 173.

In addition, an output signal Sx output from the X-axis encoder 41, an output signal Sy output from the Y-axis encoder 42, and an output signal Sz output from the Z-axis encoder 43 are transmitted to the control unit 80. Based on the output signal Sx, the output signal Sy, and the output signal Sz, the control unit 80 can grasp the position of the suction pad 173 and adjust the position of the suction pad 173.

Here, in the test apparatus 1, the applied voltage is approximately DC700 (V) and is switched at a frequency of approximately 42.0 k(Hz) in the X-axis driving unit 31, the Y-axis driving unit 32, and the Z-axis driving unit 33. In addition, the applied voltage of the motor 175 is approximately DC300 (V) and is switched at a frequency of approximately 12.5 k(Hz).

In contrast, the output voltages of the X-axis encoder 41, the Y-axis encoder 42, and the Z-axis encoder 43, that is, the voltages of the output signal Sx, the output signal Sy, and the output signal Sz are approximately AC2 (V).

In this manner, since the voltages applied to the X-axis driving unit 31, the Y-axis driving unit 32, the Z-axis driving unit 33, and the motor 175 are large relative to the output voltages of the X-axis encoder 41, the Y-axis encoder 42, and the Z-axis encoder 43, there is a possibility that noise is superimposed on the output signal Sx, the output signal Sy, and the output signal Sz.

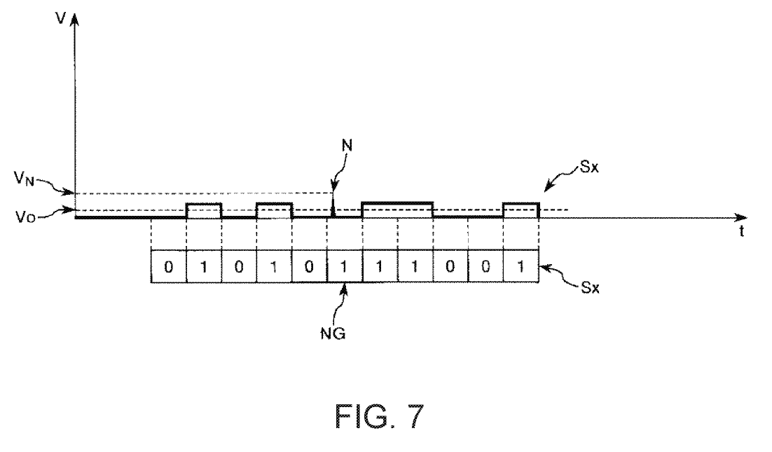

FIG. 7 is a graph illustrating a time-dependent change in the output signal Sx on which noise N is superimposed, among the output signal Sx, the output signal Sy, and the output signal Sz in the test apparatus of the related art, and the horizontal axis represents time (t) and the vertical axis represents voltage (V). As illustrated in FIG. 7, in a case where the noise N is superimposed, a voltage V_{N} of the noise N becomes greater than a predetermined voltage value V₀ depending on the degree of the voltage of the noise N. Accordingly, the output signal Sx is a signal having an error (NG). As a result, the SN ratio (a ratio of the signal amount (signal) and the noise amount (noise)) decreases, the control unit 80 cannot obtain accurate positional information of the suction pad 173, and there is a concern that an erroneous operation of the suction pad 173 is caused.

In the test apparatus 1, since the relay board 5 is provided, the above-described problem can be prevented. This will be described hereinafter.

As illustrated in FIGS. 4 and 5, in the test apparatus 1, the relay board 5 is provided between the X-axis encoder 41, the Y-axis encoder 42, and the Z-axis encoder 43, and the control unit 80. In other words, the control unit 80 is electrically connected to the position detecting unit 4 via the relay board 5.

The X-axis encoder 41, the Y-axis encoder 42, and the Z-axis encoder 43 of each of the suction pads 173 are connected to the relay board 5 via a wiring 800. Although the relay boards 5 are provided one by one in the suction units 17A and 17B, since each of the relay boards 5 has the same configuration, one relay board 5 will be representatively described hereinafter.

The relay board 5 (waveform converting unit) includes an X-axis relay board 51 which receives the output signal Sx output from the X-axis encoder 41, a Y-axis relay board 52 which receives the output signal Sy output from the Y-axis encoder 42, and a Z-axis relay board 53 which receives the output signal Sz output from the Z-axis encoder 43. The X-axis relay board 51, the Y-axis relay board 52, and the Z-axis relay board 53 are provided one by one corresponding to the number of suction pads 173.

The X-axis relay board 51 is configured with an amplifier which receives the output signal Sx, amplifies the voltage of the output signal Sx, generates an output signal Sx′, and outputs the signal to the control unit 80. The Y-axis relay board 52 is configured with an amplifier which receives the output signal Sy, amplifies the voltage of the output signal Sy, generates an output signal Sy′, and outputs the signal to the control unit 80. The Z-axis relay board 53 is configured with an amplifier which receives the output signal Sz, amplifies the voltage of the output signal Sz, generates an output signal Sz′, and outputs the signal to the control unit 80.

In this manner, the X-axis relay board 51, the Y-axis relay board 52, and the Z-axis relay board 53 function as a waveform converting unit which converts the waveform of the output signal Sx output from the X-axis encoder 41, the output signal Sy output from the Y-axis encoder 42, and the output signal Sz output from the Z-axis encoder 43. In the present embodiment, the relay board 5 (the X-axis relay board 51, the Y-axis relay board 52, and the Z-axis relay board 53) is configured with an amplifier which amplifies the voltages of the output signal Sx, the output signal Sy, and the output signal Sz, generates the output signal Sx′, the output signal Sy′, and the output signal Sz′, and outputs the signals to the control unit 80.

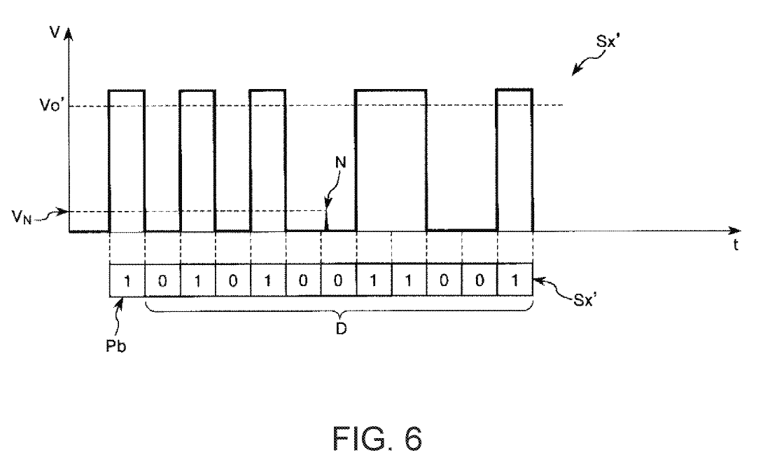

FIG. 6 is a graph representatively illustrating a time-dependent change in the output signal Sx′, and the horizontal axis represents time (t) and the vertical axis represents voltage (V). As illustrated in FIGS. 6 and 7, in the output signal Sx′, the voltage is amplified and the amplitude becomes greater than that of the output signal Sx. Further, in the test apparatus 1, the predetermined voltage value V₀′ which is a reference value of the voltage that can be regarded as a signal, that is, can be regarded as “0” or “1” in FIG. 6, is set to be a value that is greater than a predetermined voltage value V₀ set in the test apparatus of the related art. Accordingly, the voltage V_{N} of the noise N generated in a wiring 900 can be relatively reduced with respect to the voltage of the output signal Sx′. Accordingly, it is possible to prevent the voltage V_{N} of the noise N from exceeding the predetermined voltage value V₀′. In other words, it is possible to further reduce the influence when the noise N is superimposed on the output signal Sx′. Therefore, it is possible to improve the SN ratio of the output signal Sx′. As a result, it is possible to more accurately detect the positional information of the suction pad 173.

In addition, in the description above, the output signal Sx′ has been representatively described, but it is also possible to improve the SN ratio in the same manner for the output signal Sy′ and the output signal Sz′.

In particular, in the test apparatus of the related art, since the relay board 5 is omitted, the X-axis encoder 41, the Y-axis encoder 42, and the Z-axis encoder 43 are directly connected to the control unit 80 positioned at a distance by the wiring 800. In other words, there is a high possibility that the wiring 800 through which the output signal Sx, the output signal Sy, and the output signal Sz pass is relatively long and affected by the noise N. On the other hand, in the test apparatus 1, since the relay board 5 is disposed between the position detecting unit 4 and the control unit 80, the wiring 800 is shorter than that in the related art, and it is unlikely to be affected by the noise N.

In addition, in the description above, the output signal Sx has been described as an example. However, similarly to the output signal Sx, the output signal Sy and the output signal Sz can be unlikely to be affected by the noise N.

In addition, the predetermined voltage value V₀′ illustrated in FIG. 6 is preferably 2 times or more and 10 times or less the predetermined voltage value V₀ illustrated in FIG. 7, and is more preferably 4 mines or more and 8 times or less.

The relay board 5 preferably amplifies the voltage of the output signal Sx by 2 times or more and 10 times or less, and more preferably 4 mines or more and 8 times or less. Accordingly, it is possible to more effectively reduce the influence when the noise N is superimposed on the output signal Sx. When the amplification factor of the voltage of the output signal Sx is extremely large, the power consumption tends to increase and the circuit of the relay board 5 tends to be complicated. Meanwhile, when the amplification factor of the voltage of the output signal Sx is extremely small, there is a possibility that the effect of the present invention cannot be sufficiently obtained.

Further, the relay board 5 is provided on the upper surface 171a of the support substrate 171. The relay board 5 is disposed on the support substrate 171. In the device transport head 17, since the plurality of posture changing units 172 or the plurality of suction pads 173 are configured to be put together on the lower surface 171b side of the support substrate 171, and thus, it is extremely difficult to dispose the relay board 5 on the lower surface 171b side. Therefore, the configuration in which the relay board 5 is provided on the upper surface 171a of the support substrate 171, is a configuration in which the relay board 5 is disposed as close as possible to the position detecting unit 4. Accordingly, the wiring 800 having a relatively large influence when the noise N is superimposed can be shortened as much as possible. Furthermore, a wiring 900 having a relatively small influence when the noise N is superimposed can be elongated as much as possible. As a result, it is possible to more accurately detect the positional information of the suction pad 173.

In addition, in the test apparatus 1, the suction pad 173 that serves as a holding unit is disposed in the test region A3 (refer to FIG. 1) where the test of the IC device 90 is performed. Accordingly, it is possible to accurately detect the position of the suction pad 173. As a result, the IC device 90 can be accurately tested.

In addition, as illustrated in FIG. 5, the X-axis relay board 51, the Y-axis relay board 52, and the Z-axis relay board 53 are electrically connected to each other, and one (in the present embodiment, X-axis relay board 51) among the X-axis relay board 51, the Y-axis relay board 52, and the Z-axis relay board 53 is electrically connected to the control unit 80. Accordingly, it is possible to reduce the number of wirings between the relay board 5 and the control unit 80. Accordingly, it is possible to make it difficult for the noise N to be superimposed on the output signal Sx′, the output signal Sy′, and the output signal Sz′. In addition, the connection can be made by using “RS-485” which is a serial interface, for example.

In addition, in the present embodiment 1, the X-axis relay board 51, the Y-axis relay board 52, and the Z-axis relay board 53 have a function of converting the output signal Sx, the output signal Sy, and the output signal Sz, into the output signal Sx′, the output signal Sy′, and the output signal Sz′ of which errors can be detected. In other words, the X-axis relay board 51, the Y-axis relay board 52, and the Z-axis relay board 53 have a function of converting the output signal Sx, the output signal Sy, and the output signal Sz, into the output signal Sx′, the output signal Sy′, and the output signal Sz′ from which whether the noise N to the extent that errors are generated in the positional information is superimposed can be detected.

In the present embodiment, with respect to the output signal Sx, the output signal Sy, and the output signal Sz, the X-axis relay board 51, the Y-axis relay board 52, and the Z-axis relay board 53 apply a parity bit Pb (refer to FIG. 6) which is a 1-bit redundant bit to data D (refer to FIG. 6) of the positional information, generate the output signal Sx′, the output signal Sy′, and the output signal Sz′, and transmit the signals to the control unit 80. In addition, the 1-bit redundant bits are data obtained by a certain calculation method.

Based on the parity bit Pb and the data D of the positional information, the control unit 80 can determine whether or not there is an error in the data D of the positional information, that is, whether or not the noise N is superimposed on the data D of the positional information. Accordingly, it is possible to further improve the SN ratio of the output signal Sx, the output signal Sy, and the output signal Sz. As a result, it is possible to more accurately detect the positional information of each of the suction pads 173.

In addition, in the description above, as an example, a case of converting the signal into a signal of which the error can be detected by the so-called “parity check method” has been described, but well-known check method, such as a checksum method, a hamming code method, or a CRC method, may be employed.

In addition, in a case where there is an error in the received output signal Sx′, the output signal Sy′, and the output signal Sz′, the control unit 80 does not use the output signal Sx′, the output signal Sy′, and the output signal Sz′ for control, and may use the output signal Sx′, the output signal Sy′, and the output signal Sz′ that have been transmitted next for control. In addition, in a case where there is an error in the received output signal Sx′, the output signal Sy′, and the output signal Sz′, the control unit 80 may correct a location having an error in the output signal Sx′, the output signal Sy′, and the output signal Sz′ and use the location for control.

Above, as described, the electronic component handler 10 includes: the suction pad 173 that serves as a holding unit which holds the IC device 90; the position detecting unit 4 (encoder) which detects the position of the suction pad 173; the driving unit 3 which drives the suction pad 173; the control unit 80 which controls the driving of the driving unit 3; and the relay board 5 which is provided between the position detecting unit 4 and the control unit 80, and serves as a waveform converting unit which converts the waveform of the output signal output by the position detecting unit 4.

Accordingly, it is possible to reduce the influence when the noise N caused by the voltage or the like applied to the driving unit 3 is superimposed on the output signal output by the position detecting unit 4. Accordingly, it is possible to improve the SN ratio of the output signal output by the position detecting unit 4. As a result, it is possible to more accurately detect the positional information of the suction pad 173.

Furthermore, the test apparatus 1 includes: the suction pad 173 that serves as a holding unit which holds the IC device 90; the position detecting unit 4 (encoder) which detects the position of the suction pad 173; the driving unit 3 which drives the suction pad 173; the control unit 80 which controls the driving of the driving unit 3; the test unit 16 which tests the IC device 90; and the relay board 5 which is provided between the position detecting unit 4 and the control unit 80, and serves as a waveform converting unit which converts the waveform of the output signal output by the position detecting unit 4. Accordingly, it is possible to reduce the influence when the noise N caused by the voltage or the like applied to the driving unit 3 is superimposed on the output signal output by the position detecting unit 4. Accordingly, it is possible to improve the SN ratio of the output signal output by the position detecting unit 4. As a result, it is possible to more accurately detect the positional information of the suction pad 173. Therefore, the IC device 90 can be more accurately tested.

In addition, in the present embodiment, a configuration in which the suction pad 173 of the device transport head 17 provided in the test region A3 is set as “holding unit” and “driving unit”, “position detecting unit”, and “waveform converting unit” are provided in the suction pad 173 is described, but the configuration can also be applied to the device transport head 13, the device supply unit 14, the tray transport mechanism 15, the device collect unit 18, the device transport head 20, the tray transport mechanisms 21, 22A, and 22B.

### MODIFICATION EXAMPLE

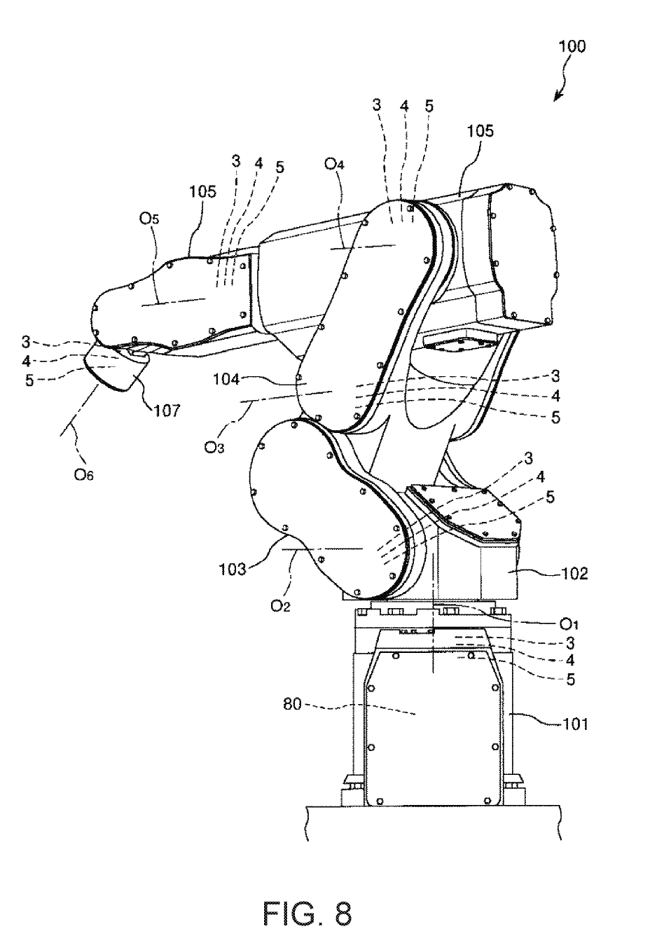

Next, based on FIG. 8, a robot which is a modification example of the electronic component handler and the electronic component tester of the present invention will be described.

FIG. 8 is a perspective view illustrating the robot which is a modification example of the electronic component handler and the electronic component tester of the present invention. Hereinafter, when viewed by a robot 100 as a whole, a base 101 side is referred to as a base end, and a sixth arm 107 side is referred to as a tip end.

As illustrated in FIG. 8, the robot 100 includes the base 101, a first arm 102, a second arm 103, a third arm 104, a fourth arm 105, a fifth arm 106, and the sixth arm 107. An end effector, such as a hand, can be attachable to and detachable from the tip end of the sixth arm 107.

The base 101 is a part installed in a ceiling, a wall, a workbench, a floor, the ground, and the like, and the control unit 80 is embedded therein.

A base end portion of the first arm 102 is rotatably connected to the base 101 around a first rotation axis O₁. A base end portion of the second arm 103 is rotatably connected to a tip end portion of the first arm 102 around a second rotation axis O₂. A base end portion of the third arm 104 is rotatably connected to a tip end portion of the second arm 103 around a third rotation axis O₃. A base end portion of the fourth arm 105 is rotatably connected to a tip end portion of the third arm 104 around a fourth rotation axis O₄. A base end portion of the fifth arm 106 is rotatably connected to a tip end portion of the fourth arm 105 around a fifth rotation axis O₅. A base end portion of the sixth arm 107 is rotatably connected to a tip end portion of the fifth arm 106 around a sixth rotation axis O₆.

In addition, at a part connected to the base 101 of the first arm 102, the driving unit 3 which drives the first arm 102 around the first rotation axis O₁, the position detecting unit 4 which detects the position of the driving unit 3, the relay board 5 which amplifies the voltage of the output signal output by the position detecting unit 4, are embedded.

In addition, at a part connected to the first arm 102 of the second arm 103, the driving unit 3 which drives the second arm 103 around the second rotation axis O₂, the position detecting unit 4 which detects the position of the driving unit 3, the relay board 5 which amplifies the voltage of the output signal output by the position detecting unit 4, are embedded.

In addition, at a part connected to the second arm 103 of the third arm 104, the driving unit 3 which drives the third arm 104 around the third rotation axis O₃, the position detecting unit 4 which detects the position of the driving unit 3, the relay board 5 which amplifies the voltage of the output signal output by the position detecting unit 4, are embedded.

In addition, at a part connected to the third arm 104 of the fourth arm 105, the driving unit 3 which drives the fourth arm 105 around the fourth rotation axis O₄, the position detecting unit 4 which detects the position of the driving unit 3, the relay board 5 which amplifies the voltage of the output signal output by the position detecting unit 4, are embedded.

In addition, at a part connected to the fourth arm 105 of the fifth arm 106, the driving unit 3 which drives the fifth arm 106 around the fifth rotation axis O₅, the position detecting unit 4 which detects the position of the driving unit 3, the relay board 5 which amplifies the voltage of the output signal output by the position detecting unit 4, are embedded.

In addition, at a part connected to the fifth arm 106 of the sixth arm 107, the driving unit 3 which drives the sixth arm 107 around the sixth rotation axis O₆, the position detecting unit 4 which detects the position of the driving unit 3, the relay board 5 which amplifies the voltage of the output signal output by the position detecting unit 4, are embedded.

In addition, each of the relay boards 5 is electrically connected to the control unit 80 via the wiring (not illustrated), and the output signals amplified by each of the relay boards 5 are respectively transmitted to the control unit 80.

According the robot 100, it is possible to reduce the influence when the noise caused by the voltage or the like applied to the driving unit 3 is superimposed, for example, on the output signal output by the position detecting unit 4. Accordingly, it is possible to improve the SN ratio of the output signal output by the position detecting unit 4. As a result, it is possible to more accurately detect the positional information of the driving unit 3. Therefore, it is possible to accurately perform work performed by the robot 100, for example, assembly or transportation of precision components.

In this manner, the present invention can also be applied to the robot 100. In addition, in the description above, the so-called “single arm type robot” has been described as an example of the robot 100, but the present invention is not limited thereto, for example, a dual arm robot or a robot having three or more arms, may be employed.

As above, the electronic component handler and the electronic component tester of the present invention are described using the embodiments illustrated in the drawing, but the present invention is not limited thereto, and each portion which configures the electronic component handler and the electronic component tester can be replaced with any configuration that can achieve similar functions. In addition, any configuration member may be added.

In addition, the electronic component handler and the electronic component tester of the present invention may combine two or more configurations (characteristics) of each of the embodiments.

In the above-described embodiment, as an example of the conversion of the waveform converting unit, an amplifier which amplifies the voltage has been described as an example, but the present invention is not limited thereto, for example, as long as a function of reducing the influence of noise by converting the waveform of the output signal, such as a low pass filter, is provided.

The entire disclosure of Japanese Patent Application No. 2016-035345, filed Feb. 26, 2016, is expressly incorporated by reference herein.

1. An electronic component handler comprising:
a holding unit which holds an electronic component;
a base portion on which the holding unit is movably disposed;
a position detecting unit which detects a relative position between the base portion and the holding unit;
a driving unit which drives the holding unit;
a control unit which controls driving of the driving unit; and
a waveform converting unit which is provided between the position detecting unit and the control unit and converts a waveform of an output signal output by the position detecting unit.

2. The electronic component handler according to claim 1, wherein the control unit is electrically connected to the position detecting unit via the waveform converting unit.

3. The electronic component handler according to claim 1,
wherein the waveform converting unit amplifies a voltage of the output signal.

4. The electronic component handler according to claim 3, wherein the waveform converting unit amplifies the voltage of the output signal by 2 times or more and 10 times or less.

5. The electronic component handler according to of claim 1,
wherein the position detecting unit is an encoder.

6. The electronic component handler according to of claim 1,
wherein a plurality of the driving units and the encoders are provided.

7. The electronic component handler according to claim 6,
wherein, when three axes that cross each other are respectively set as an X axis, a Y axis, and a Z axis,
the driving unit includes an X-axis driving unit which drives the holding unit in the X-axis direction, a Y-axis driving unit which drives the holding unit in the Y-axis direction, and a Z-axis driving unit which rotates the holding unit around the Z axis, and
the encoder includes an X-axis encoder which detects a position of the holding unit driven by the X-axis driving unit in the X-axis direction, a Y-axis encoder which detects a position of the holding unit driven by the Y-axis driving unit in the Y-axis direction, and a Z-axis encoder which detects a position of the holding unit driven by the Z-axis driving unit around the Z axis.

8. The electronic component handler according to claim 7,
wherein, when the X-axis driving unit and the X-axis encoder are X-axis units, the Y-axis driving unit and the Y-axis encoder are Y-axis units, and the Z-axis driving unit and the Z-axis encoder are Z-axis units,
a plurality of the X-axis units, the Y-axis units, and the Z-axis units are provided.

9. The electronic component handler according to claim 1,
wherein the waveform converting unit has a function of converting the output signal into a signal of which an error is detectable.

10. The electronic component handler according to claim 1,
wherein a plurality of the waveform converting units are provided, and
wherein the waveform converting units is electrically connected to the other and one waveform converting unit of the waveform converting units is electrically connected to the control unit.

11. The electronic component handler according to claim 1,
wherein the driving unit includes a piezo actuator that serves as a driving source.

12. The electronic component handler according to claim 1, further comprising:
a support substrate which supports the holding unit,
wherein the waveform converting unit is disposed on the support substrate.

13. The electronic component handler according to claim 1,
wherein the holding unit is disposed in a test region where test of the electronic component is performed.

14. An electronic component tester comprising:
a holding unit which holds an electronic component;
a base portion on which the holding unit is movably disposed;
a position detecting unit which detects a relative position between the base portion and the holding unit;
a driving unit which drives the holding unit;
a control unit which controls driving of the driving unit;
a waveform converting unit which is provided between the position detecting unit and the control unit and converts a waveform of an output signal output by the position detecting unit; and
a test unit which tests the electronic component.
